(19) United States
(12) Patent Application Publication
(10) Pub. No.: US 2007/0063727 A1
(43) Pub. Date: Mar. 22, 2007

(54) Apparatus and method for measuring TFT pixel driving current

(75) Inventor: Yasuhiro Miyake, Tokyo (JP)

Correspondence Address: Paul D. Greeley;Ohlandt, Greeley, Ruggiero & Perle, L.L.P., One Landmark Square, 10th Floor, Stamford, CT, 06901-2682, US

(73) Assignee: Agilent Technologies, Inc.

(21) Appl. No.: 11/506,140

(22) Filed: Aug. 17, 2006

(30) Foreign Application Priority Data
Sep. 20, 2005 (JP) 2005-272442

(51) Int. Cl. G01R 31/00

(52) U.S. Cl. 324/770

(57) ABSTRACT

A method for measuring the pixel driving current, characterized in that it comprises a first step for measuring the offset current flowing to wiring when multiple pixels are all set to the non-lighted state; a second step for measuring the pixel driving current of a predetermined pixel from the difference between the current flowing to the wiring when only a predetermined pixel of the multiple pixels is lighted and this offset current; a third step for repeating the second step, measuring in succession the pixel driving current of a predetermined number of pixels from the multiple pixels, and then resetting all of the multiple pixels to the non-lighted state; and a fourth step for repeating from the first step to the third step and measuring the pixel driving current of the display device, etc.

### FIELD OF THE INVENTION

The present invention relates to a method and apparatus for measuring the pixel driving current and in particular, to a method and apparatus for measuring the pixel driving current of a display device having a structure with which the pixel driving current of multiple pixels is distributed and supplied from a common wiring.

### DISCUSSION OF THE BACKGROUND ART

In display devices that use self-emitting light-emitting elements such as EL elements, the light-emitting elements are sealed in an active matrix substrate for controlling the luminance of each light-emitting element to create a display panel. Self-emitting light-emitting elements generally emit light at a luminance corresponding to the current flowing to the element (pixel driving current). Active matrix substrates have the function of controlling the emission luminance by controlling the pixel driving current of each pixel. The pixel driving current is often controlled by the control voltage using an FET. That is, as shown in FIG. 6, a light-emitting element 66 is connected to the drain terminal of a transistor 64 and the current that is supplied to light-emitting element 66 is controlled by controlling the drain-source current using gate voltage. A holding capacitor 65 is generally disposed at the gate terminal in order to keep the gate voltage constant. Moreover, the pixel driving current that is supplied to the source terminal often has a layout such that it is distributed and supplied from one wiring 62A for supplying the driving current to each pixel in order to minimize the amount of wiring inside a substrate.

The control circuit on the active matrix substrate is produced by means of relatively unstable layer-forming steps, such as sputtering on the glass substrate, and the like; therefore, it is necessary to test whether or not each pixel on the substrate has the desired function before shipping the finished display device. One of the test items is the measurement of the pixel driving current. This measurement is conducted by the following procedure. First, holding capacitor 65 of the pixel being measured is set at the desired voltage. Holding capacitor 65 is connected to the gate terminal of transistor 64 for controlling the pixel current; then current corresponding to the set voltage, that is, the gate voltage, is allowed to flow between the drain and the source. The pixel driving current flowing at this time is measured. It is possible to determine whether or not transistor 64 for controlling the pixel driving current of the measured pixel is operating correctly by determining whether or not the measurement result is within a desired current range. It is possible to determine whether or not a display device has predetermined properties by conducting this type of measurement and making a quality determination for all pixels on a substrate.

It is, of course, preferred that the pixel driving current of each pixel is measured independently when measuring this pixel driving current. However, as previously mentioned, the pixel driving current is structured such that it is distributed and supplied from a single wiring 62A for supplying the driving current; therefore, it is not possible to measure the current from a predetermined pixel only. Consequently, the pixel driving current of a measured pixel is generally found by measuring the current flowing to the wiring for supplying the driving current when one or multiple pixels to be measured in a display device are lighted and the other pixels are in the non-lighted state.

However, it is difficult to completely insulate circuit pixels from one another in a semiconductor integrated circuit such as an active matrix substrate, and a very small leakage current is therefore present. A very small leakage current flows even when measurement is not being conducted, because it is not possible to bring the pixel driving current between the drain and source all the way down to zero. Therefore, some current flows to the wiring for supplying driving current that supplies the pixel driving current to multiple pixels, even if all of the pixels are in the non-lighted state. This current is called the offset current.

Analogously to the technology disclosed in Japanese Patent No. 3628014, the offset current is subtracted from the current flowing to wiring 62A when the pixels to be measured are lighted and the pixel driving current is found, in order to eliminate the effect of this offset current when the pixel driving current is being measured. The method whereby the measured value that includes the offset current is converted to a digital value and the offset current is subtracted by data processing is one method for subtracting the offset current component at this time. However, it is necessary to measure current that includes the offset current component by this method. Therefore, it is necessary to enlarge the measurement range of the ammeter and it is difficult to obtain precise measurement accuracy. Therefore, there is another method whereby a constant-current circuit for canceling the offset current is disposed in parallel with the ammeter, the offset current is canceled with hardware, and only the pixel driving current is measured by the ammeter.

However, the above-mentioned leakage current is produced not only between the drain and source, but also from holding capacitor 65. The leakage current from holding capacitor 65 changes voltage between the terminals of the holding capacitor. As a result, the gate voltage changes and current flows between the drain and the source in accordance with the gate voltage. In other words, the current between the drain and the source is not only the leakage current attributed to the insulation properties between the above-mentioned drain and source; current is also generated by changes in the gate voltage that have been produced by the leakage current from holding capacitor 65. Of these, the leakage current attributed to insulation properties is constant, but because there is an increase in the amount of electrification of holding capacitor 65 as time passes during which pixel driving voltage is applied to wiring 62A, the current produced by changes in the gate voltage increases with the time during which the pixel driving voltage is applied. However, p-type MOS transistor 64 has voltage-current properties such as shown in FIG. 5; therefore, when the value of the gate source voltage Vgs moves to the left from the point of intersection of the coordinate axes, the absolute value of the drain source current Ids increases nonlinearly. Therefore, the offset current that flows from wiring 62A for supplying driving current increases rapidly over time. FIG. 5 shows an example of the voltage-current properties of a p-type MOS transistor. The direction of the current and voltage polarity change with the polarity of the transistor.

There are as many as, for instance, 500,000 or more, pixels in a display device (there are 786,432 pixels in an XGA) and it therefore takes the equivalent amount of time to measure the pixel driving current of the entire display device. Therefore, when offset current that is produced by changes in the gate voltage is neglected, the offset current increases and an offset current exceeding the measured amount flows to wiring 62A for supplying the driving current. When measurement is performed under conditions of such a large offset current, it must be performed within a large measurement range; therefore, measurement of high accuracy becomes difficult. Moreover, precise measurement is not possible without a function capable of precise cancellation of the offset current that changes with the passage of time during which pixel driving voltage is applied to wiring 62A. Therefore, there is a need for a measurement method and apparatus capable of eliminating the effects of offset current produced by changes in gate voltage and able to conduct a highly accurate measurement of the pixel driving current.

By means of the conventional example disclosed in Japanese Patent No. 3628014, the dynamic range of the measured current is narrowed and a high-precision measurement is performed by disposing a constant-current circuit for canceling the offset current in parallel to the ammeter, canceling the offset current with hardware, and measuring only the pixel driving current with the ammeter. Nevertheless, when multiple pixels are measured in succession, there is a nonlinear increase over time in the percentage of increase in the offset current value 41, as shown in FIG. 10. That is, there is a gradual increase in the absolute value of the offset current as B1, B2, B3 and B4, and there is a gradual increase in the percentage change as well, from B1 to B2, B2 to B3, and B3 to B4. As a result, the dynamic range needed for the constant-current source that cancels the offset current also increases and it is therefore difficult to supply current precisely. Moreover, there is also a possibility that the offset current value of the pixel under test will deviate from a specific value for a variety of reasons. Consequently, the dynamic range of driving current 42 to be measured of the pixel under test is virtually constant, as shown in FIG. 10A, and even if a high precision of the ammeter can be maintained, there is a chance that the precision of offset current cancellation will decrease and the measurement precision of the system as a whole will decrease.

### SUMMARY OF THE INVENTION

The above-mentioned problems can be solved by a method for measuring pixel driving current, characterized in that it comprises a first step for measuring the offset current flowing to the wiring when multiple pixels are all set to the non-lighted state; a second step for measuring the pixel driving current of a predetermined pixel from the difference between the current flowing to the wiring when only a predetermined pixel of the multiple pixels is lighted and this offset current; a third step for repeating said second step, measuring in succession the pixel driving current of a predetermined number of pixels from the multiple pixels, and then resetting all of the multiple pixels to the non-lighted state; and a fourth step for repeating from the first step to the third step and measuring the pixel driving current of the display device, etc.

By means of the present invention, it is possible to provide a measuring method and apparatus capable of eliminating the effect of offset current that is produced by changes in control voltage and making possible a high-precision measurement of pixel driving current.

### BRIEF DESCRIPTION OF THE DRAWINGS

FIG. 1 is a schematic drawing of the measurement device described in an embodiment of the present invention.

FIG. 2 is an explanatory drawing of the internal circuit of the display device of an embodiment of the present invention.

FIG. 3 is an operational flow chart of the measuring apparatus of an embodiment of the present invention.

FIG. 4 is a graph showing the number of measured pixels and the changes in offset current and the measured current.

FIG. 5 is a graph showing the voltage-current properties of a transistor inside a pixel.

FIG. 6 is an explanatory drawing of the internal circuit of the display device.

FIG. 7 is a schematic drawing of the measurement device described in another embodiment of the present invention.

FIG. 8 is an explanatory drawing of the internal circuit of the display device of another embodiment of the present invention.

FIG. 9 is another operational flow chart of the measuring apparatus of an embodiment of the present invention.

FIG. 10 is another graph showing the number of measured pixels and the changes in offset current and measured current.

FIG. 11 is a circuit drawing showing an embodiment wherein the present invention is used in an active matrix that employs an EL element substitution load.

FIG. 12 is a circuit drawing showing load 19 in FIG. 11.

### DETAILED DESCRIPTION OF THE PREFERRED EMBODIMENT

Typical working examples of the present invention will now be given while referring to the drawings.

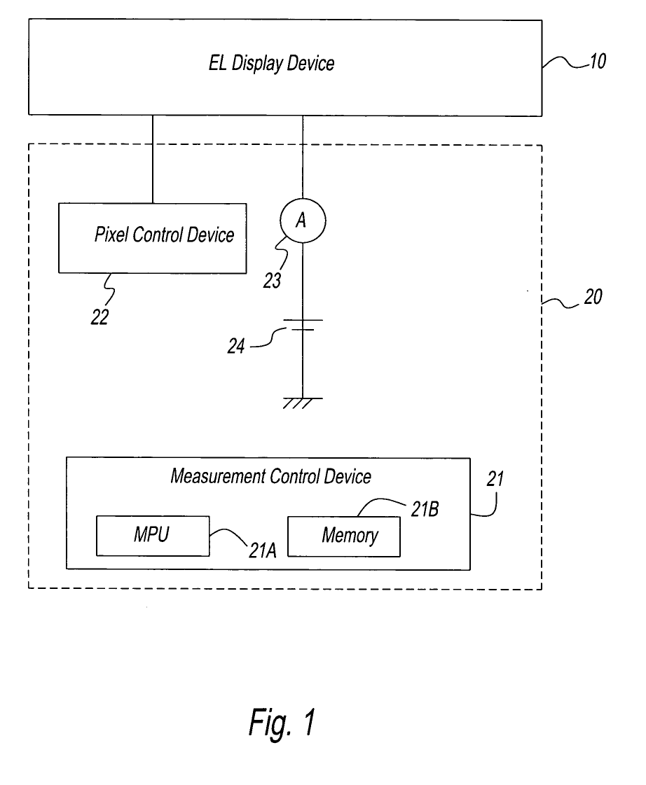

FIG. 1 is a sketch of an apparatus 20 for measuring the pixel driving current of the present invention. Measuring apparatus 20 comprises a pixel control device 22 for controlling the lighted state of the pixels of an EL display device 10, which is a self-emitting-type display element; a power source 24 for applying pixel driving voltage to the wiring for supplying the driving current for display device 10; an ammeter 23 disposed between power source 24 and the wiring for supplying the driving current; and a measurement control device 21 for controlling the operation of measuring apparatus 20.

Pixel control device 22 has the function of specifying the pixel of display device 10 to be measured, controlling the lighted/non-lighted state of the measured pixel, and controlling the emission luminance of the pixel to be measured. Moreover, measurement control device 21 has an MPU 21A, which is a data processing means, and a hard disk memory 21B, and programs in which the measurement control method of the present invention are written are housed inside memory 21B.

It should be noted that the display device that is the subject of the measurement is not limited to EL display device 10 and can be any display device with which light-emitting elements having the property whereby luminance is controlled by the driving current flowing to the elements are driven using an active matrix substrate having the function whereby the pixel driving current is controlled by a control voltage. Moreover, the data processing means of measurement control device 21 is not necessarily an MPU and can be any device having a digital data mathematic operation function, such as a DSP. The memory means is not necessarily a hard disk and can be any device capable of housing digital data, such as a flash memory or RAM.

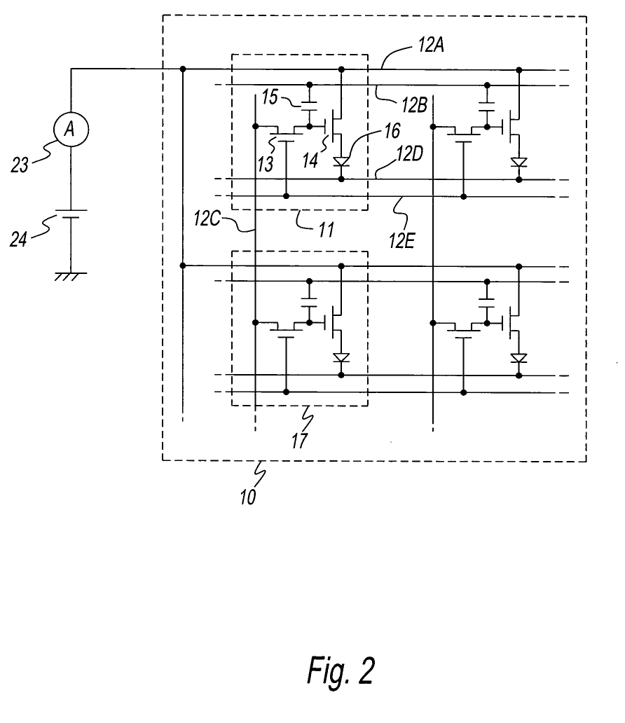

The structure of EL display device 10 that is the subject of measurement is shown in FIG. 2. EL display device 10 has pixels 11 disposed in matrix form and a wiring 12A for supplying the pixel driving current, a common line 12B of a holding capacitor 15, a data line 12C, a common line 12D for pixel driving current, and a gate line 12E connected to each pixel. Ammeter 23 and power source 24 of measuring apparatus 20 are connected to wiring 12A of this layout. Common line 12D for the pixel driving current is set at the same potential as the ground potential of display device 20. Unless otherwise specified, the voltage in the following description is the potential difference from the voltage of common line 12D.

Pixel 11 comprises a transistor 13 for pixel selection that selects the measured pixel that is the subject of control; a transistor 14, which is the element for controlling the pixel driving current; holding capacitor 15, which holds the gate voltage of the transistor for controlling the pixel driving current; and an EL element 16. The gate terminal of transistor 13 for pixel selection is connected to gate line 12E, the source terminal is connected to data line 12C, and the drain terminal is connected to the gate terminal of transistor 14 for controlling the pixel driving current and one end of holding capacitor 15. Transistor 14 for controlling the pixel driving current is connected to the drain terminal of transistor 13 for pixel selection and one end of holding capacitor 15, the source terminal is connected to wiring 12A, and the drain terminal is connected to one end of EL element 16.

One end of holding capacitor 15 is connected to the drain terminal of transistor 13 for pixel selection and the gate terminal of transistor 14 for controlling the pixel driving current, and the other end is connected to common line 12B. One end of EL element 16 is connected to the drain terminal of transistor 14 for controlling the pixel driving current, and the other end is connected to common line 12D. It should be noted that transistor 13 for pixel selection and transistor 14 for controlling the pixel driving current are both p-type MOS transistors, but they can also be an n-type MOS transistor or a transistor with a structure other than an MOS structure.

The operation of pixel 11 will now be described. The phrase “conducting state” in the present Specification and Claims means a state whereby the impedance between the drain and source of the transistor is low. Transistor 13 for pixel selection and transistor 14 for controlling the pixel driving current both have voltage-current properties such as shown in FIG. 5 in the present working example and are therefore in a conducting state when the gate voltage is controlled such that the gate-source voltage is 0 V or less. FIG. 5 shows the voltage-current properties of the gate-source voltage and the drain-source current in a conducting state. EL element 16 is in an emitting state when transistor 14 for controlling the pixel driving current is in a conducting state.

On the other hand, a “non-conducting state” means a state wherein the impedance between the drain and source of the transistor is high. A pixel is in a non-conducting state when the gate-source voltage is higher than 0 V. EL element 16 is in a non-emitting state when transistor 14 for controlling the pixel driving current is in a non-conducting state. However, as previously shown, even in a non-conducting state, leakage current attributed to insulation properties flows unless the current between the drain and source is brought all the way down to zero.

Pixel 11 is selected by bringing gate line 12E to 0 V. A voltage of 10 V is normally applied to gate line 12E and only the gate line 12E that has been selected by pixel control device 22 is brought to 0 V. As a result, transistor 13 for pixel selection is in a conducting state, and the control voltage of data line 12C is applied to holding capacitor 15. Control voltage (emission luminance signal) is supplied from pixel control device 22 to data line 12C at this time. When the control voltage is 5 V or higher, EL element 16 is in the non-lighted state and when it is less than 5 V, the EL element is in the lighted state. Luminance gradually increases with a reduction in the control voltage in the lighted state and the element emits under maximum intensity when the voltage is 0 V. 5 V is always applied to common line 12B.

Holding capacitor 15 that holds the control voltage is connected to the gate terminal of transistor 14 for controlling the pixel driving current; therefore, the pixel driving current that corresponds to the control voltage flows between the drain and source of transistor 14. The pixel driving current is supplied from wiring 12A to which pixel driving voltage is applied through transistor 14 to EL element 16.

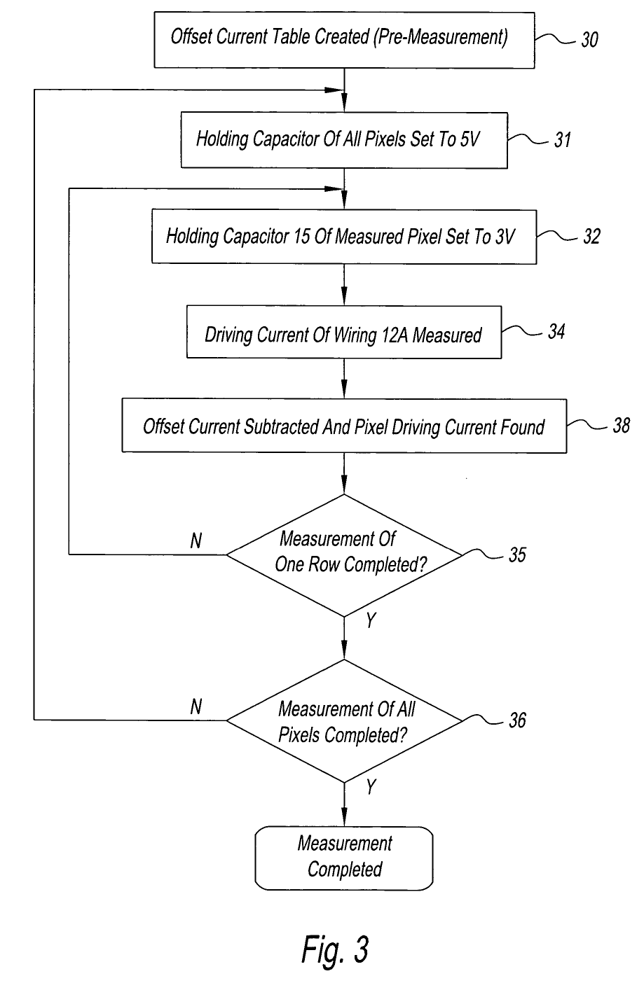

Next, the operation of apparatus 20 for measuring the pixel driving current will be described. FIG. 3 is a flow chart showing the operation of measuring apparatus 20. The measurement is comprised of two measurements, a pre-measurement whereby a table is created that shows the correlation between the offset current and the number of pixels that have been measured (number of measured pixels) after the holding capacitors of all pixels of display panel 20 have been set to the non-lighted state inside memory 21B (step 30) and then an actual measurement by the measurement method of the present invention (steps 31 to 36).

As previously mentioned, the offset current changes with the time during which pixel driving voltage is applied to wiring 12A after the holding capacitors of all elements have been set to the non-lighted state. Therefore, in essence, it is necessary to measure the correlation between the application time and the offset current, measure the time during which the pixel driving voltage is applied during this measurement, and find the offset current from the time between when the holding capacitors of all pixels have been set to the non-lighted state and the time when the pixel driving current is measured. However, by means of apparatus 20 for measuring the pixel driving current, the pixel driving current is measured under a constant timing and the pixel driving voltage continues to be applied during measurement; therefore, the time during which the pixel driving voltage is applied and the number of measured pixels are proportional. Consequently, the number of measured pixels is used in the pre-measurement as a substitute for the time during which the pixel driving voltage is applied. Consequently, by means of an apparatus for measuring the pixel driving current with an irregular measurement timing, it is necessary to find the correlation between the time during which the pixel driving voltage is applied and the offset current as previously described.

By means of the pre-measurement (step 30), the holding capacitors of all pixels of display panel 10 (that is, the gate terminal of transistor 14) for controlling the pixel driving current) are set at 5 V (non-lighted state) and the driving current flowing to wiring 12A is measured by ammeter 23. The current value measured at that time is the offset current value when the number of measured pixels is 0. Next, holding capacitor 15 of the appropriate pixel (that is, the gate terminal of transistor 14 for controlling the pixel driving current) is set to 3 V (lighted state), then it is reset to 5 V (non-lighted state), and the driving current of wiring 12A is measured by ammeter 23. The current measured at this time is the offset current when the number of measured pixels is 1. At this time, the control voltage is set under the same timing as the actual measurement beginning with step 31.

The same lighting/non-lighting operation is conducted for the pixels under the same timing as the actual measurement, the offset current is measured, and the offset current when the number of measured pixels is 2 is found. The optimal position of the pixel measured by pre-measurement is selected such that whenever possible, it is the same state as that of the actual measurement, which is described later, but it is not limited to this position, depending on the conditions. For instance, when only the number of measured pixels is important, the pixel can be at a completely different position, including the same position as a pixel for which has been found the offset current when the number of measured pixels is 1. The lighting/non-lighting operation of the pixels is repeated and the correlation between the number of measured pixels and the offset current is recorded in the table in memory 21B.

As previously mentioned, the voltage (gate voltage of transistor 14) of holding capacitors 15 of other pixels on display device 10 changes with the leakage current as lighting/non-lighting operation of the pixels is being performed, and current between the drain and source of each pixel increases. Therefore, the offset current when the number of measured pixels is 1 is a large value when compared to the offset value when the number of measured pixels is 0. Furthermore, the offset current suddenly changes as the number of measured pixels increases (time passes).

It should be noted that when the change in the offset value of display device 10 is known in advance, pre-measurement is not necessary and actual measurement can be conducted after the table has been stored in memory 21B. Moreover, when finding the pixel driving current by the actual measurement using the correlation between the time during which the pixel driving voltage is applied and the offset current, it is possible to set all pixels to the non-lighted state, apply the pixel driving voltage to wiring 12A, measure the offset current for each pre-determined time interval, and then record the correlation between the time during which the measurements were conducted and the offset current in the table.

Next, the actual measurement, which is the measuring method of the present invention, will now be described (steps 31, 32, 34, 38, 35, and 36). In the actual measurement, the holding capacitors of all pixels of display device 10 are set at 5 V (Step 31). There is no current flowing to transistor 14 for controlling the pixel driving current of all pixels during this step other than the leakage current between the drain and source. Next, holding capacitor 15 of measured pixel 11 in line 1 of the first row is set at 3 V (step 32). The voltage that is set at this time can be set as needed in accordance with the measurement conditions, but 3 V is the measurement condition in the present working example.

Moreover, the current that flows to wiring 12A is measured by ammeter 23 (step 34). Next, using the data when the number of measured pixels is 0 in the table of the offset current values stored in memory 21B, the offset current value is subtracted from the measurement value and the measurement value of the pixel driving current is found (step 38).

The measured current is stored in memory 21B together with the position of the pixel (line 1 of row 1) and the gate voltage (3 V). Holding capacitor 15 of measured pixel 11 is eventually set at 5 V (non-lighted state).

Next, the pixel driving current of measured pixel 17 in line 2 of row 1 is measured. First, the holding capacitor of measured pixel 17 is set to 3 V (step 32). Then the current flowing to wiring 12A is measured by ammeter 23 (step 34). Next, using the offset current value data when the number of measured pixels is 1 in the table of the offset current value stored in memory 21B, the offset current value is subtracted from the value measured with the ammeter and the pixel driving current value is found (step 38). The measurement that has been found is stored in memory 21B together with the position of the pixel (line 2 of row 1) and gate voltage (3 V). The measured value stored in memory 21B at this time is the difference between the value of the current flowing to wiring 12A and the offset current value. Finally, holding capacitor 15 of measured pixel 17 is set at 5 V (non-lighted state). The pixel driving current of all pixels in row 1 is measured in succession by the same process.

When the measurement of all pixels in row 1 has been completed (step 35), the holding capacitors of all pixels in display device 10 are reset to 5 V (non-lighted state (step 31)). By means of this resetting, the pixels return to a state wherein there is no current other than the leakage current between the drain and the source flowing to transistor 14 for controlling the pixel driving current of all pixels. The process in steps 32, 34, and 38 is then repeated and the pixel driving current of each pixel in row 2 is measured in succession. The measured values in step 38 are calculated at this time by calling from memory 21B the offset current values corresponding to the number of measured pixels once the pixels have been reset and finding the difference from the measured current. For instance, when the pixel in line 1 of row 2 is measured, the offset current value is set at the value when the number of measured pixels is 0 and when the pixel in line 2 of row 2 is measured, the offset current value is set at the value when the number of measured pixels is 1.

When each pixel is measured in succession in this way and all pixels on display device 10 have been measured (step 36), the measurement operation of measuring apparatus 20 is completed. MPU 21A is used to assess whether or not the measured value of each pixel stored in memory 21B falls within the standard range as necessary and to determine the quality of display device 10.

When the pixel driving current is measured using the correlation between the time during which the pixel driving voltage is applied and the offset current, the time that has passed since the multiple elements were all set to the non-lighted state is found and the measurements are corrected using the offset current value corresponding to the resulting time from the table stored in memory 21B. When offset current values corresponding to the lapsed time are not entered in the table, it is possible to find the offset current value using the offset current corresponding to the most recent time or by interpolating the data using MPU 21A.

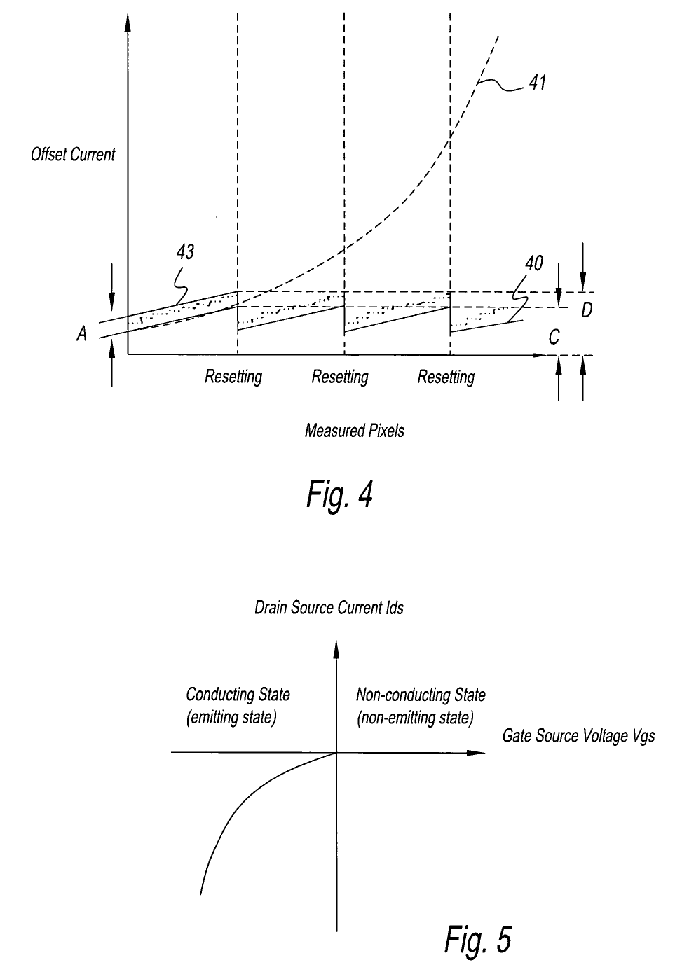

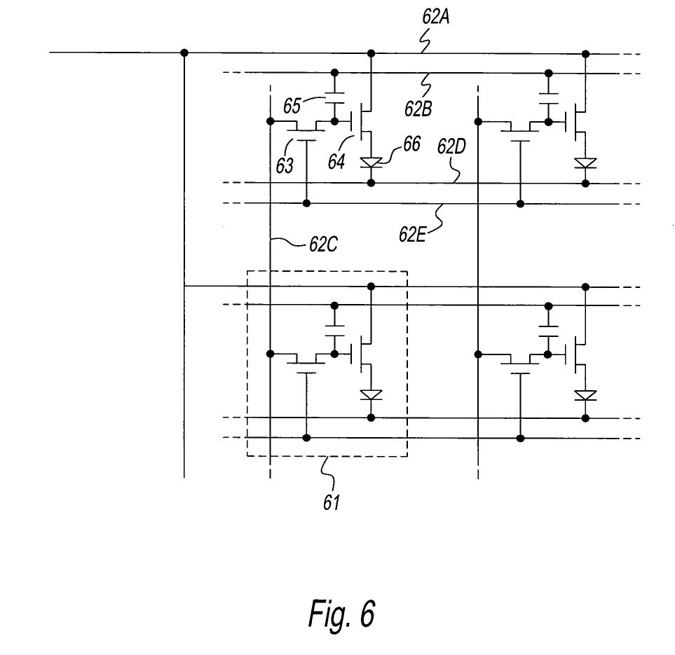

FIG. 4 shows the changes (solid curve 40) in the offset current when the voltage of holding capacitor 15 has been reset to the non-lighted state during the course of the measurement by the working example of the present invention versus the changes (broken curve 41) in the offset current when the measurement is continued without resetting. For convenience, solid curve 40 and broken curve 41 are drawn as straight lines and a curved line, but the actual offset current values are physical amounts obtained by the pre-measurement as described above and are strictly discontinuous values entered in a table. Moreover, broken curve 43 showing the driving current measured values is drawn in steps, but this simply schematically shows the measured values of an object under test, and the layout of the points in the drawing has no special meaning. As is clear from the figure, as a result of resetting, the offset current value is periodically returned to the initial value; therefore, the increase in the offset current during the measurement procedure is controlled and the dynamic range of the offset current can be kept within the range shown by C in the figure. The dynamic range of the measured driving current is the range shown by A in the figure, and the dynamic range necessary for ammeter 23 can be kept within the range shown by A+C, that is, D, in the figure. Therefore, it is possible to prevent a reduction in the measurement accuracy. Moreover, the offset current returns to the initial value each time one row is measured. Consequently, a table in which changes in the offset current during the measurement procedure are recorded becomes unnecessary, and the contents of the table can be reduced.

By means of the present embodiment, the time when the voltage of holding capacitor 15 is reset to the non-lighted state during the measurement procedure is when the measurement of one row of pixels of EL display device 10 is completed and before the measurement of the second row is started. However, the time of resetting is not limited to this example. For instance, the voltage can be reset sometime during the measurement of the first row, or after the measurement of multiple rows. Moreover, the time when the voltage is reset can be predetermined such that it is kept within the measurement range of ammeter 23. It is also possible to monitor the measured values of ammeter 23 with measurement control device 21 and to reset the voltage when a predetermined value is exceeded.

The present working example has described the case where the offset current value is found for each pixel by pre-measurement, but when a device with small changes over time in the offset current is being measured, it is possible to find the pixel driving current by finding the difference between the current flowing to wiring 12A and the offset current when the number of measured pixels is 0 (initial value). In this case, the pre-measurement is simplified (only the offset current when the number of measured pixels is 0 is measured), and a high-speed measurement becomes possible. Furthermore, there is an advantage in that a large table is not needed and there is a further reduction in the storage capacity of memory 21B.

Another working example of the present invention will now be described while referring to the drawings.

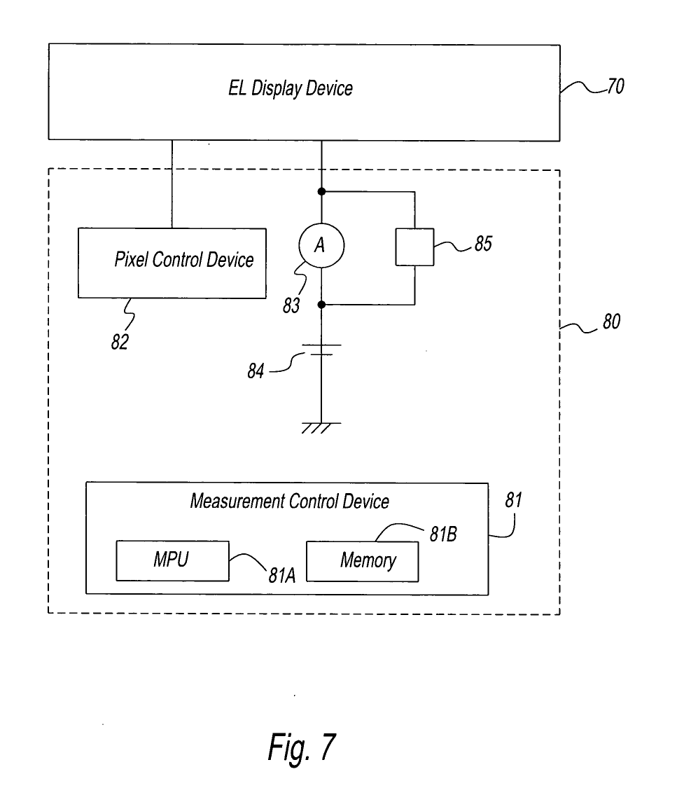

FIG. 7 is a sketch of an apparatus 80 for measuring the pixel driving current of the present invention. Measuring apparatus 80 comprises a pixel control device 82 for controlling the lighted state of the pixels of an EL display device 70, which is a self-emitting-type display element; a power source 84 for applying pixel driving voltage to the wiring for supplying the driving current of display device 70; an ammeter 83 disposed between power source 84 and the wiring for supplying the driving current; a constant-current circuit 85 connected in parallel with ammeter 83; and a measurement control device 81 for controlling the operation of measuring apparatus 80.

Pixel control device 82 has the function of specifying the pixel of display device 70 to be measured, controlling the lighted/non-lighted state of the pixel to be measured, and controlling the emission luminance of the pixel to be measured. Moreover, measurement control device 81 has an MPU 81A, which is a data processing means, and a hard disk memory 81B, and programs on which the measurement control method of the present invention are written are housed inside memory 81B. Constant-current circuit 85 is a circuit having the function whereby a constant current flows, and may be a circuit for generating a predetermined current itself (current source), or a circuit for allowing the passage of only a predetermined current from power source 84 (the remainder of the current flows through ammeter 82) (circuit for controlling current).

It should be noted that the display device that is the subject of the measurement is not limited to EL display device 70 and can be any display device with which light-emitting elements having the property whereby luminance is controlled by the driving current flowing to the elements are driven using an active matrix substrate having the function whereby the pixel driving current is controlled by a control voltage. Moreover, the data processing means of measurement control device 81 is not necessarily an MPU and can be any device having a digital data mathematic operation function, such as a DSP. The memory means is not necessarily a hard disk and can be any device capable of housing digital data, such as a flash memory or a RAM.

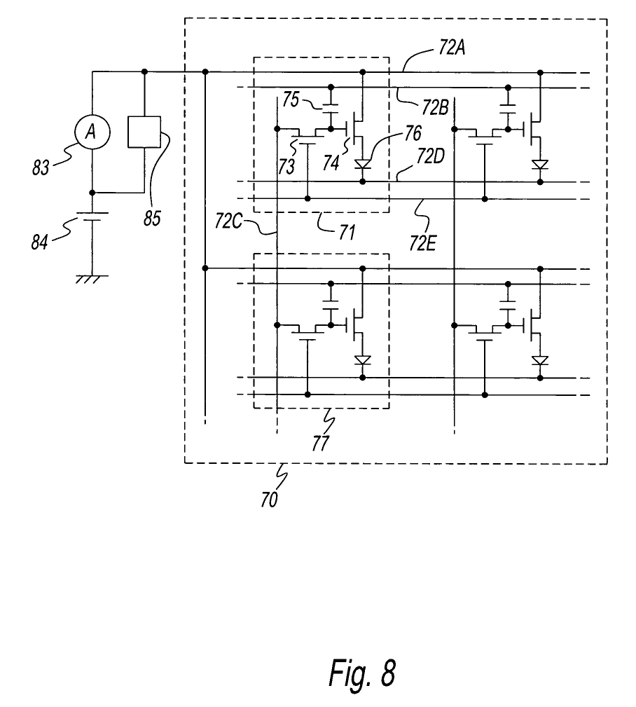

The structure of EL display device 70 that is the subject of measurement is shown in FIG. 8. EL display element 70 has pixels 71 disposed in matrix form and a wiring 72A for supplying the pixel driving current, a common line 72B of a holding capacitor 75, a data line 72C, a common line 72D for the pixel driving current, and a gate line 72E connected to each pixel. Of these, ammeter 83 and power source 84 of measuring apparatus 80 are connected to wiring 72A. Common line 72D for the pixel driving current is set at the same potential as the ground potential of display device 80. Unless otherwise specified, the voltage in the following description is the potential difference from the voltage of common line 72D.

Pixel 71 comprises a transistor 73 for pixel selection that selects the pixel to be measured that is the subject of control; a transistor 74, which is the element for controlling the pixel driving current; holding capacitor 75, which holds the gate voltage of the transistor for controlling the pixel driving current; and an EL element 76. The gate terminal of transistor 73 for pixel selection is connected to gate line 72E, the source terminal is connected to data line 72C, and the drain terminal is connected to the gate terminal of transistor 74 for controlling the pixel driving current and one end of holding capacitor 75. Transistor 74 for controlling the pixel driving current is connected to the drain terminal of transistor 73 for pixel selection and one end of holding capacitor 75, the source terminal is connected to wiring 72A, and the drain terminal is connected to one end of EL element 76.

One end of holding capacitor 75 is connected to the drain terminal of transistor 73 for pixel selection and the gate terminal of transistor 74 for controlling the pixel driving current, and the other end is connected to common line 72B. One end of EL element 76 is connected to the drain terminal of transistor 74 for controlling the pixel driving current, and the other end is connected to common line 72D. It should be noted that transistor 73 for pixel selection and transistor 74 for controlling the pixel driving current are both p-type MOS transistors, but they can also be an n-type MOS transistor or a transistor with a structure other than an MOS structure.

The operation of pixel 71 will now be described. The phrase “conducting state” in the present Specification and Claims means a state whereby the impedance between the drain and source of the transistor is low. Transistor 73 for pixel selection and transistor 74 for controlling the pixel driving current both have voltage-current properties such as is shown in FIG. 5 in the present working example and are therefore in a conducting state when the gate voltage is controlled such that the gate-source voltage is 0 V or less. FIG. 5 shows the voltage-current properties of the gate-source voltage and the drain-source current in a conducting state. EL element 76 is in an emitting state when transistor 74 for controlling the pixel driving current is in a conducting state.

On the other hand, a “non-conducting state” means a state wherein the impedance between the drain and source of the transistor is high. A pixel is in a non-conducting state when the gate-source voltage is higher than 0 V. EL element 76 is in a non-emitting state when transistor 74 for controlling the pixel driving current is in a non-conducting state. However, as previously shown, even in a non-conducting state, the leakage current attributed to insulation properties flows unless the current between the drain and source is brought all the way down to zero.

Pixel 71 is selected by bringing gate line 72E to 0 V. A voltage of 7 V is normally applied to gate line 72E and only the gate line 72E that has been selected by pixel control device 82 is brought to 0 V. As a result, transistor 73 for pixel selection is in a conducting state, and the control voltage of data line 72C is applied to holding capacitor 75. Control voltage (an emission luminance signal) is supplied from pixel control device 82 to data line 72C at this time. When the control voltage is 5 V or higher, EL element 76 is in the non-lighted state and when it is less than 5 V, the EL element is in the lighted state. Luminance gradually increases with a reduction in the control voltage in the lighted state and the element emits under maximum intensity when the voltage is 0 V. 5 V is always applied to common line 72B.

Holding capacitor 75 that holds the control voltage is connected to the gate terminal of transistor 74 for controlling the pixel driving current; therefore, the pixel driving current that corresponds to the control voltage flows between the drain and source of transistor 74. The pixel driving current is supplied from wiring 72A to which pixel driving voltage is applied through transistor 74 to EL element 76.

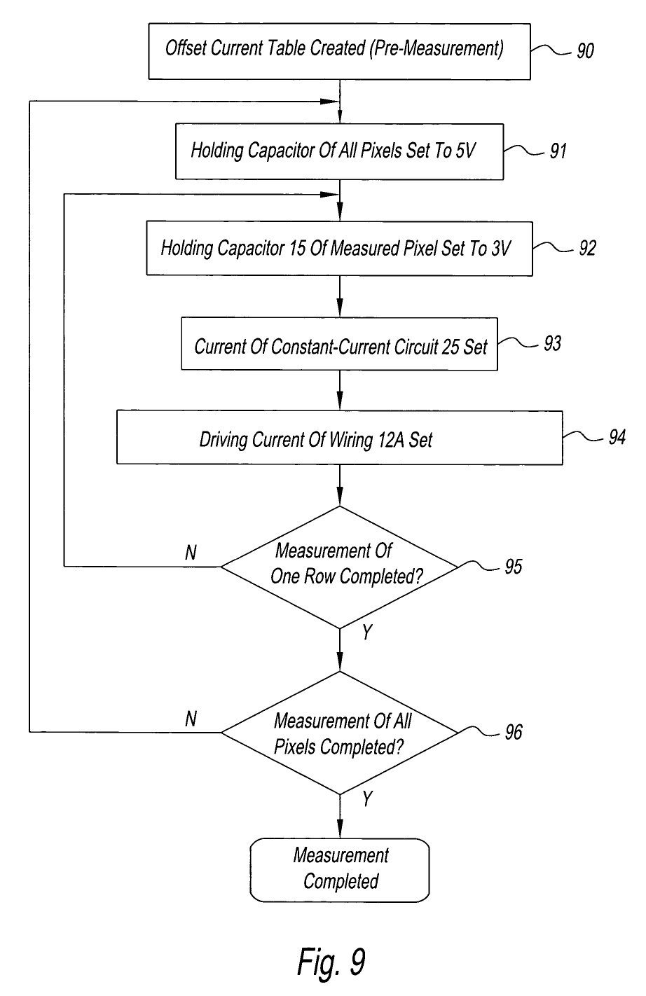

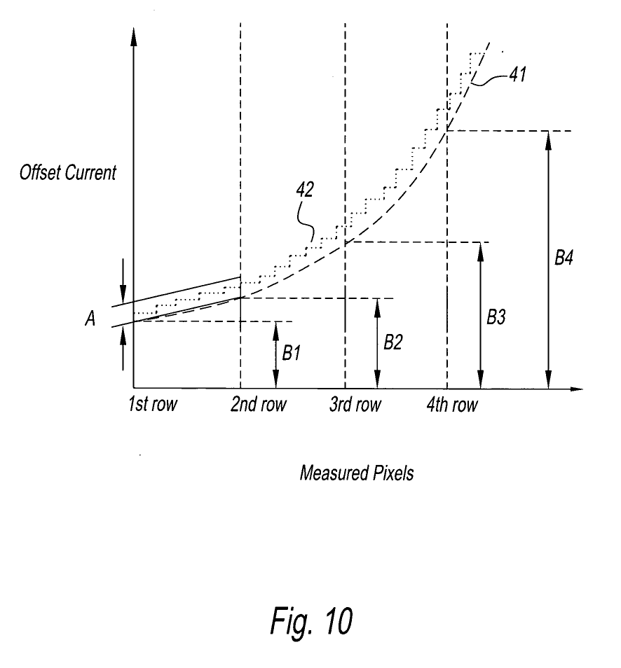

Next, the operation of apparatus 80 for measuring the pixel driving current will be described. FIG. 9 is a flow chart showing the operation of measuring apparatus 80. The measurement is comprised of two measurements, a pre-measurement whereby a table is created that shows the correlation between the offset current and the number of pixels that have been measured (number of measured pixels) after the holding capacitor for all pixels of display panel 70 has been set to the non-lighted state inside memory 81B (step 90), and the actual measurement by the measurement method of the present invention (steps 91 to 96).

As previously mentioned, the offset current changes with the time during which the pixel driving voltage is applied to wiring 72A after the holding capacitor of all elements has been set to the non-lighted state. Therefore, in essence, it is necessary to measure the correlation between the application time and the offset current, to measure the time during which the pixel driving voltage is applied during this measurement, and find the offset current from the time between when the holding capacitor of all pixels has been set to the non-lighted state and the time when the pixel driving current is measured. However, by means of apparatus 80 for measuring the pixel driving current, the pixel driving current is measured under constant timing and the pixel driving voltage continues to be applied during the measurement; therefore, the time during which the pixel driving voltage is applied and the number of measured pixels are proportional. Consequently, the number of measured pixels is used in the pre-measurement as a substitute for the time during which the pixel driving voltage is applied. Consequently, by means of an apparatus for measuring the pixel driving current with irregular measurement timing, it is necessary to find the correlation between the time during which the pixel driving voltage is applied and the offset current as previously described.

By means of the pre-measurement (step 90), the holding capacitor of all pixels of display panel 70 (that is, the gate terminal of transistor 74) for controlling the pixel driving current) is set at 5 V (non-lighted state) and the driving current flowing to wiring 72A is measured by ammeter 82. The current value measured at that time is the offset current value when the number of measured pixels is 0. Next, holding capacitor 75 of the appropriate pixel (that is, the gate terminal of transistor 74 for controlling the pixel driving current) is set to 3 V (lighted state), then it is reset to 5 V (non-lighted state), and the driving current of wiring 72A is measured by ammeter 82. The current measured at this time is the offset current when the number of measured pixels is 1. At this time, the control voltage is set under the same timing as the actual measurement beginning with step 91.

The same lighting/non-lighting operation is conducted for the pixels under the same timing as the actual measurement, the offset current is measured, and the offset current when the number of measured pixels is 2 is found. The position of the measured pixel at this time can be the same pixel as the pixel for which the offset current has been found when the number of measured pixels is 1, or it can be a different pixel. The same lighting/non-lighting procedure of the pixel is similarly performed and the correlation between the number of measured pixels and the offset current is recorded in the table in memory 81B.

As previously mentioned, the voltage (gate voltage of transistor 74) of holding capacitor 75 of other pixels on display device 70 changes with the leakage current as the lighting/non-lighting operation of the pixels is being performed, and the current between the drain and source of each pixel increases. Therefore, the offset current when the number of measured pixels is 1 is a large value when compared to the offset value when the number of measured pixels is 0. Furthermore, the offset current suddenly changes as the number of measured pixels increases (time passes).

It should be noted that when the change in the offset value of display device 10 is known in advance, a pre-measurement is not necessary and the actual measurement can be conducted after the table has been stored in memory 81B. Moreover, when finding the pixel driving current by the actual measurement using the correlation between the time for which the pixel driving voltage is applied and the offset current, it is possible to set all pixels to the non-lighted state, apply the pixel driving voltage to wiring 12A, to measure the offset current for each pre-determined time interval, and then to record the correlation between the time during which the measurements were conducted and the offset current in the table.

Next, the actual measurement, which is the measuring method of the present invention, will now be described (steps 91 through 96). By means of the actual measurement, the holding capacitor of all pixels of display device 70 is set at 5 V (step 91). There is no current flowing to transistor 74 for controlling the pixel driving current of all pixels during this step other than the leakage current between the drain and source. Next, holding capacitor 75 of measured pixel 71 in line 1 of the first row is set at 3 V (step 92). The voltage that is set at this time can be set as needed in accordance with the measurement conditions, but 3 V is the measurement condition in the present working example. Next, the current of constant-current circuit 85 is set at the offset current when the number of measured pixels is 0 from the table stored in memory 81B (step 93).

Moreover, the current that flows to wiring 72A is measured by ammeter 83 (step 94). Thus, of the current flowing to wiring 72A, the offset current flows to wiring 72A through constant-current circuit 85 without passing through ammeter 83. Only the pixel driving current of the measured pixel can be measured by ammeter 83. As a result, it becomes possible to measure the pixel driving current within a smaller measurement range and to measure current with greater accuracy. The measured current is stored in memory 81B together with the position of the pixel (line 1 of row 1) and the gate voltage (3 V). Holding capacitor 75 of measured pixel 71 is eventually set at 5 V (non-lighted state).

Then the pixel driving current of measured pixel 77 at line 2 of row 1 is measured. First, the holding capacitor of measured pixel 77 is set at 3 V (step 92). Next, the current of constant-current circuit 85 is set as the offset current when the number of measured pixels is 1, taken from the table stored in memory 81B (step 93). Then the current flowing to wiring 72A is measured by ammeter 83 (step 94). The measured current is stored in memory 81B together with the position of the pixel (line 1 of row 1) and the gate voltage (3 V). Holding capacitor 75 of measured pixel 77 is eventually set at 5 V (non-lighted state). The pixel driving current of all pixels in the first row is measured in succession by the same process.

When the measurement of all pixels in row 1 has been completed (step 95), the holding capacitor of all pixels in display device 70 is reset to 5 V (non-lighted state (step 91)). By means of this resetting, the pixels return to a state wherein there is no current flowing to transistor 74 other than the leakage current between the drain and the source for controlling the pixel driving current of all pixels. The process in steps 92 through 94 is then repeated and the pixel driving current of each pixel in row 2 is measured in succession. The current of the constant-current circuit 85 set in step 93 is set at this time by calling up the offset current corresponding to the number of measured pixels after resetting from memory 81B. For instance, when the pixel in line 1 of row 2 is measured, the current of constant-current circuit 85 is set at the offset current when the number of measured pixels is 0 and when the pixel in line 2 of row 2 is measured, the current of constant-current circuit 85 is set at the offset current when the number of measured pixels is 1.

When each pixel is measured in succession in this way and all pixels on display device 70 have been measured (step 96), the measurement operation of measuring apparatus 80 is completed. MPU 81A is used to assess whether or not the measured value of each pixel stored in memory 81B falls within the standard range as necessary and to determine the quality of display device 70.

When setting the current of constant-current circuit 85 in step 93 when the pixel driving current is measured using the correlation between the time for which the pixel driving voltage is applied and the offset current, the time that has passed since multiple elements were all set to the non-lighted state is found and the offset current corresponding to the resulting time is found from the table stored in memory 81B and the current is set. When offset current values corresponding to the lapsed time are not entered in the table, it is possible to find the offset current value using the offset current corresponding to the most recent time or by interpolating the data using MPU 81A.

FIG. 4 shows the changes (solid curve 40) in the offset current when the voltage of holding capacitor 15 has been reset to the non-lighted state during the course of measurement by the working example of the present invention versus the changes (broken curve 41) in the offset current when the measurement is continued without resetting. As is clear from the figure, as a result of resetting, the offset current value is periodically returned to the initial value; therefore, the increase in the offset current during the measurement procedure is controlled and the dynamic range of the offset current can be kept within the range shown by C in the figure. The measured current is cancelled by constant-current circuit 85 that is set at the offset current value; therefore, the dynamic range needed for ammeter 83 is kept within the range shown by A in the figure. Therefore, the accuracy of the measurements can be improved. The offset current returns to the initial value each time one row is measured. The table in memory 81B for determining the current of constant-current circuit 85 therefore can be secured by the number of pixels in one row. Consequently, a table in which changes in the offset current during the measurement procedure are recorded becomes unnecessary, and the contents of the table can be reduced.

By means of this other working example as well, the pixel driving current is found by canceling the increment change in the offset current from the correlation between the number of measured pixels (or the time for which pixel driving voltage is applied to wiring 72A) and the offset current. However, when the resetting procedure (step 91) is used frequently, or a device is being measured that shows small changes over time in the offset current, the pixel driving current can be found by finding the difference between the current flowing to wiring 72A and the offset current when the number of measured pixels is 0 (initial value). In this case, the pre-measurement is simplified (only the offset current when the number of measured pixels is 0 is measured) and it is not necessary to set the current of constant-current circuit 85 for each measurement; therefore, high-speed measurement becomes possible. Furthermore, there is an advantage in that a large table is not needed and there is a further reduction in the storage capacity of memory 81B.

The technological concept of the present invention has been described in detail while referring to specific working examples, but it will be obvious to persons skilled in the art of the present invention that various modifications and changes can be made without deviating from the gist and scope of the claims. For instance, an FET was used in the present working examples as the element for controlling the pixel driving current, but the present invention can also be applied to a display element that uses another current control element, such as an operational amplifier circuit. Moreover, by means of the present working examples, holding capacitors 15 and 75 for holding control voltage were used and EL elements 16 and 76 were periodically reset to the non-lighted status by initializing the control voltage (resetting the voltage of holding capacitors 15 and 75), but it is also possible to use another means for applying constant voltage and to curb the increase in the offset current by initializing the status of this application means and periodically resetting EL elements 16 and 76 to the non-lighted state.

Moreover, a cycle for resetting to the non-lighted state is not necessary for each row as in the present working examples, and resetting can be performed every several pixels if the changes over time in the offset current are large, or every several rows if the changes are small. Therefore, it is possible to refer to the amount of change in the offset current once the pre-measurement is completed (steps 30 and 90) and determine for what number of pixels the resetting should be performed using measurement control devices 21 and 81. Moreover, the pixels that are the subject of resetting are not necessarily all of the pixels of the display device as in the present working example. Once the pixels have been returned to the non-lighted state, resetting can be performed using only those pixels that have been measured a predetermined number of times. Furthermore, the pixels that are the subject of the measurement are not necessarily adjacent pixels measured in succession as in the working examples. It is possible to measure every several pixels or to measure pixels randomly.

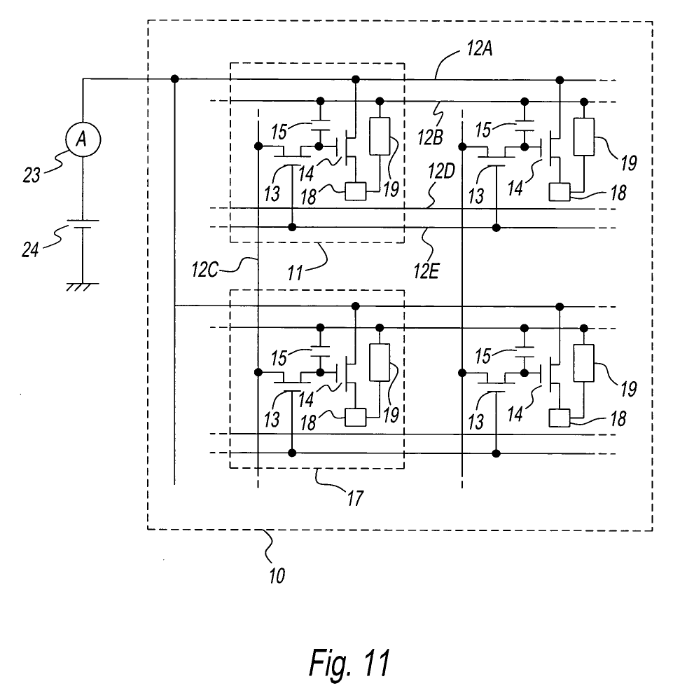

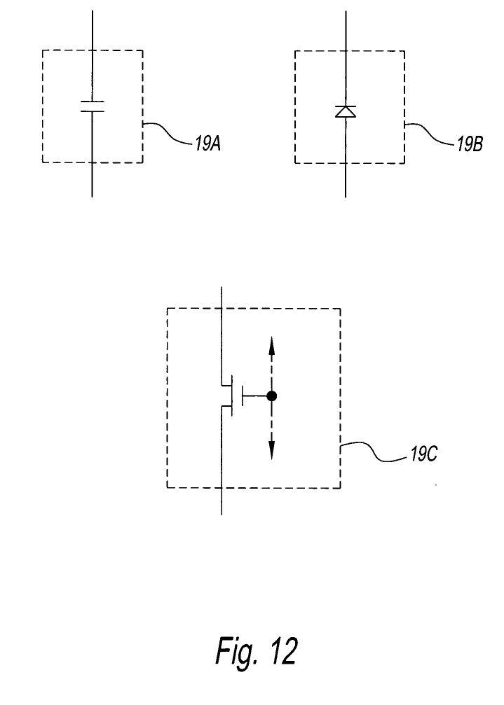

The present working examples described an EL display device 10 using an active matrix substrate after the EL elements were formed, but the present invention can also be applied to a circuit wherein a measurement load that is substituted for the EL elements (substitution load) is disposed on the open-circuit electrodes on the matrix substrate before forming the EL elements, for instance, the circuit described in JP (Kokai) 2004-294,457. In this case, the term “lighted” in the present specification means a state of current control such that the EL element is lighted once it has been mounted on the substrate. FIG. 11 shows part of the circuit of an active matrix substrate with such a substitution load. This circuit has an electrode 18 disposed where the EL element should be formed and a load 19 connected between this electrode 18 and wiring 12B. A capacitor 19A, a diode 19B, a transistor 19C, and the like can be used for load 19, as shown in FIG. 12. When transistor 19C is used, a new gate line for controlling the value of the load is disposed at the active matrix substrate. For these circuits in FIG. 11, the same reference numbers will be used for the structural parts that are the same as in the working example shown in FIG. 2 and a detailed description is therefore omitted. It should be noted that a circuit that uses a substitution load for the EL element on the substrate before the EL element has been molded can also be used with the working example in FIG. 8.

The above-mentioned working examples present a description of cases in which the offset current value is premeasured and stored in a table. The method whereby pre-measurement is performed and the offset current value is stored in a table is very advantageous in terms of measurement speed. However, the present invention is not limited to this example and it is possible to repeatedly measure the offset current and the pixel driving current for each pixel when extremely high measurement precision is necessary. In this case, first the offset current is measured in a non-lighted state, the pixel is brought to a lighted state and the pixel driving current is measured, the difference between the offset current and the measured current remains as the result, and the pixel is returned to a non-lighted state. It is possible to reset all pixels to a non-lighted state under the appropriate timing, not only when one row of the pixels has been measured, but also when the number of measured pixels exceeds a certain number, when the measurement time exceeds a certain time, when the measured values exceed a certain value, and the like.

What is claimed is:

1. A measurement method for measuring the pixel driving current of a display device having wiring for supplying the driving current to multiple pixels, said measurement method comprising
a first step for measuring the offset current flowing to said wiring when said multiple pixels are all set to the non-lighted state;
a second step for measuring said pixel driving current of a predetermined pixel from the difference between the current flowing to said wiring when only a predetermined pixel of said multiple pixels is lighted and said offset current;
a third step for repeating said second step, measuring in succession said pixel driving current of a predetermined number of pixels from said multiple pixels; and then resetting all of said multiple pixels to the non-lighted state; and
a fourth step for repeating from said first step to said third step and measuring said pixel driving current of said display device.

2. The measurement method according to claim 1, wherein said pixels have pixel driving current control elements for controlling said pixel driving current based on a control voltage, and said third step is conducted for resetting all of said multiple pixels to the non-lighted state by resetting said control voltage to the voltage at which said pixel driving current control elements become non-conducting.

3. The measurement method according to claim 1, wherein the difference between the current flowing to said wiring and said offset current is found by mathematical operation from digital data on measurement values of current flowing to said wiring and digital data of offset current values pertaining to the pixel in question.

4. The measurement method according to claim 1, wherein said first step is a step for measuring the correlation between the time for which pixel driving voltage is applied to said wiring and said offset current, and said second step comprises a step for finding the offset current from the correlation found in said first step with the time for which pixel driving voltage is applied to said wiring since said multiple pixels have all been set to the non-lighted state.

5. The measurement method according to claim 1, wherein said first step is a step for measuring the correlation between the number of measured pixels and said offset current, and said second step comprises a step for measuring said offset current from the correlation found in said first step with the number of measured pixels after said multiple pixels have all been set to the non-lighted state.

6. The measurement method according to claim 1, wherein said pixels are the substitution load for measurement.

7. A computer readable storage media containing executable computer program instructions which when executed cause a processing system to perform a measurement method for measuring the pixel driving current of a display device having wiring for supplying the driving current to multiple pixels, said measurement method comprising
a first step for measuring the offset current flowing to said wiring when said multiple pixels are all set to the non-lighted state;
a second step for measuring said pixel driving current of a predetermined pixel from the difference between the current flowing to said wiring when only a predetermined pixel of said multiple pixels is lighted and said offset current;
a third step for repeating said second step, measuring in succession said pixel driving current of a predetermined number of pixels from said multiple pixels; and then resetting all of said multiple pixels to the non-lighted state; and
a fourth step for repeating from said first step to said third step and measuring said pixel driving current of said display device.

8. A measuring apparatus for measuring the pixel driving current of a display device having wiring for supplying the driving current to multiple pixels having pixel driving current control elements for controlling said pixel driving current based on the control voltage, said measuring apparatus comprises:
a power source for supplying said driving current to said wiring;
an ammeter disposed in between said power source and said wiring;
a pixel control device for supplying signals for controlling the lighted state of each pixel of said multiple pixels; and
a measurement control device that has data processing means and memory means and is used for implementing a) a first step for setting said multiple pixels all to the non-lighted state and measuring the offset current flowing to said wiring after the setting, b) a second step for measuring in succession the driving current of each of a predetermined number of pixels from said multiple pixels based on the difference between the current flowing to said wiring when each of said pixels is lighted and said offset current, and c) a third step for repeating said first and second steps and measuring the pixel driving current of the pixels of said display device.

9. The measurement apparatus according to claim 8, wherein said pixel driving current control elements are transistors.

10. The measurement apparatus according to claim 8, wherein said measurement apparatus also has a constant-current circuit connected in parallel with said ammeter and in that the same current as said offset current flows to said constant-current circuit.

11. The measurement apparatus according to claim 8, wherein said first step comprises a step for using said pixel control device to set said control voltage to the voltage at which said pixel driving current control elements are in the non-lighted state.

12. The measurement apparatus according to claim 8, wherein said pixels are
a substitution load for measurement.
